(19) United States
(12) Patent Application Publication
(10) Pub. No.: US 2024/0243069 A1
(43) Pub. Date: Jul. 18, 2024

(54) ELECTRONIC DEVICE

(71) Applicant: Innolux Corporation, Miaoli County (TW)

(72) Inventors: Hsiu-Yi Tsai, Miaoli County (TW); Yi-Hung Lin, Miaoli County (TW); Nai-Fang Hsu, Miaoli County (TW)

(73) Assignee: Innolux Corporation, Miaoli County (TW)

(21) Appl. No.: 18/402,654

(22) Filed: Jan. 2, 2024

Related U.S. Application Data
(60) Provisional application No. 63/439,586, filed on Jan. 18, 2023.

(30) Foreign Application Priority Data
Sep. 8, 2023 (CN) 202311158768.7

(51) Int. Cl. H01L 23/538

(52) U.S. Cl. CPC H01L 23/5386; H01L 24/16; H01L 2224/16227

(57) ABSTRACT

An electronic device includes a substrate, a metal layer, a first dielectric layer, a first conductive circuit, and a driving chip. The metal layer is provided on the substrate and has a first opening. The first dielectric layer is provided on the metal layer. The first conductive circuit is provided on the first dielectric layer. The driving chip is provided on the first dielectric layer and electrically connected to the first conductive circuit. The first opening is adjacent to the driving chip. The first conductive circuit overlaps the first opening. The electronic device of the disclosure may reduce the risk of a short circuit between the conductive circuit and the metal layer below when performing patching, function analysis, or failure analysis.

### CROSS-REFERENCE TO RELATED APPLICATION

This application claims the priority benefit of the U.S. provisional application Ser. No. 63/439,586, filed on Jan. 18, 2023, and China application Ser. No. 20/231,1158768.7, filed on Sep. 8, 2023. The entirety of each of the above-mentioned patent applications is hereby incorporated by reference herein and made a part of this specification.

### BACKGROUND

### Technical Field

The disclosure relates to an electronic device, and more particularly, to an electronic device that may reduce the risk of a short circuit between a conductive circuit and a metal layer below when performing patching, function analysis, or failure analysis.

### Description of Related Art

Electronic devices or splicing electronic devices has been widely applied in different fields such as communication, display, vehicle, or aviation. With the vigorous development of electronic devices, the electronic devices are becoming thinner and lighter, which has led to higher requirements for the reliability or quality of the electronic devices.

### SUMMARY

The disclosure provides an electronic device that may reduce the risk of a short circuit between the conductive circuit and the metal layer below when performing patching, function analysis, or failure analysis.

According to the embodiment of the disclosure, the electronic device includes a substrate, a metal layer, a first dielectric layer, a first conductive circuit, and a driving chip. The metal layer is provided on the substrate and has a first opening. The first dielectric layer is provided on the metal layer. The first conductive circuit is provided on the first dielectric layer. The driving chip is provided on the first dielectric layer and electrically connected to the first conductive circuit. The first opening is adjacent to the driving chip. The first conductive circuit overlaps the first opening.

### BRIEF DESCRIPTION OF THE DRAWINGS

The accompanying drawings are included to provide a further understanding of the disclosure, and are incorporated in and constitute a part of this specification. The drawings illustrate embodiments of the disclosure, and together with the description serve to explain principles of the disclosure.

FIG. 1A is a top schematic view of the electronic device in the first embodiment of the disclosure.

FIG. 1B is an enlarged schematic view of the area R of the electronic device in FIG. 1A.

FIG. 1C is a cross-sectional schematic view of the electronic device in FIG. 1B along a profile line I-I′.

FIG. 2 is a partial top schematic view of the electronic device in the second embodiment of the disclosure.

FIG. 3 is a partial top schematic view of the electronic device in the third embodiment of the disclosure.

FIG. 4A is a partial top schematic view of the electronic device in the fourth embodiment of the disclosure.

FIG. 4B is a cross-sectional schematic view of the electronic device in FIG. 4A along a profile line II-II′.

FIG. 5 is a partial top schematic view of the electronic device in the fifth embodiment of the disclosure.

FIG. 6 is a partial top schematic view of the electronic device in the sixth embodiment of the disclosure.

FIG. 7 is a partial top schematic view of the electronic device in the seventh embodiment of the disclosure.

FIG. 8 is a partial top schematic view of the electronic device in the eighth embodiment of the disclosure.

FIG. 9 is a partial top schematic view of the electronic device in the ninth embodiment of the disclosure.

### DESCRIPTION OF THE EMBODIMENTS

The disclosure can be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. In addition, the number and size of each of the elements in the figures are for illustration purposes only, and are not intended to limit the scope of the disclosure.

In the following description and claims, words such as “comprising” and “including” are open-ended words, so they should be interpreted as meaning “including but not limited to . . . ”.

It should be understood that when an element or layer is referred to as being “on” or “connected to” another element or layer, it may be directly on or directly connected to this other element or layer, or there may be an intervening element or layer in between (indirect case). In contrast, when an element is referred to as being “directly on” or “directly connected to” another element or layer, there are no intervening elements or layers present.

Although the terms “first”, “second”, “third”, . . . may be used to describe various constituent elements, the constituent elements are not limited by the terms. The terms are only used to distinguish a single constituent element from other constituent elements in the specification. The same terms may not be used in the claim, but replaced by first, second, third . . . according to the order in which the elements are declared in the claim. Therefore, in the following description, the first constituent element may be the second constituent element in the claim.

As used herein, the terms “about,” “approximately,” “substantially,” and “roughly” generally mean within 10%, within 5%, within 3%, within 2%, within 1%, or within 0.5% of a given value or range. The quantity given here is an approximate quantity, that is, even though “about,” “approximately,” “substantially,” and “roughly” are not specified, the meaning of “about,” “approximately,” “substantially,” and “roughly” are still implied.

In some embodiments of the disclosure, terms related to joining and connecting, such as “connected”, “interconnected”, etc., unless otherwise defined, may mean that two structures are in direct contact, or may also mean that two structures are not in direct contact, in which there are other structures located between these two structures. The terms related to joining and connecting can also include the case where both structures are movable, or both structures are fixed. Furthermore, the term “coupled” includes any direct and indirect means of electrical connection.

In some embodiments of the disclosure, optical microscopy (OM), scanning electron microscope (SEM), film thickness profiler (α-step), ellipsometer, or other suitable methods may be used to measure the area, width, thickness, or height of each element, or the distance or pitch between elements. In detail, according to some embodiments, a scanning electron microscope can be used to obtain a cross-sectional structure image including a component to be measured, and to measure the area, width, thickness, or height of each element, or the distance or pitch between elements.

The electronic device of this disclosure may include a display device, an antenna device, a communication device, a sensing device, or a splicing device, but is not limited thereto. The electronic device may be a bendable or flexible electronic device. The electronic device may for example, include a liquid crystal light emitting diode; the light emitting diode may include, for example, an organic light-emitting diode (OLED), a mini light-emitting diode (mini LED), a micro light-emitting diode (micro LED), or a quantum dot light-emitting diode (quantum dot, QD, such as QLED, QDLED), fluorescence, phosphor, or other suitable materials, and the materials can be any arrangement and combination, but not limited thereto. The antenna device may be, for example, a phase array antenna, but is not limited thereto. The splicing device may be, for example, a display splicing device or an antenna splicing device, but not limited thereto. It should be noted that, the electronic device can be any arrangement and combination of the foregoing, but not limited thereto. Hereinafter, an electronic device is used to illustrate the disclosure, but the disclosure is not limited thereto.

It should be noted that, in the following embodiments, the features in several different embodiments can be replaced, reorganized, and mixed to complete other embodiments without departing from the spirit of the disclosure. As long as the features of the various embodiments do not violate the spirit of the disclosure or conflict with one another, they can be mixed and matched arbitrarily.

References of the exemplary embodiments of the disclosure are to be made in detail. Examples of the exemplary embodiments are illustrated in the drawings. If applicable, the same reference numerals in the drawings and the descriptions indicate the same or similar parts.

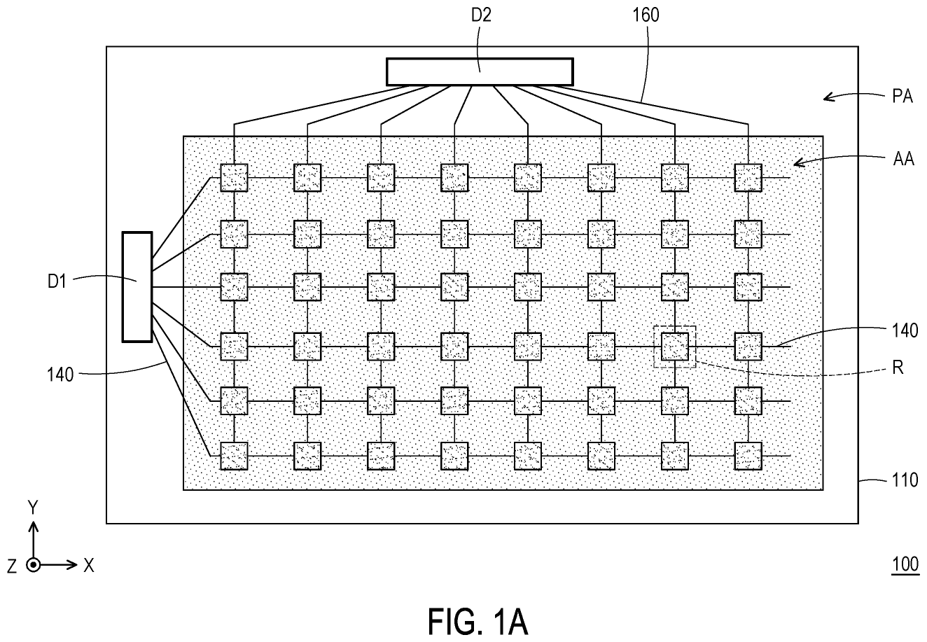

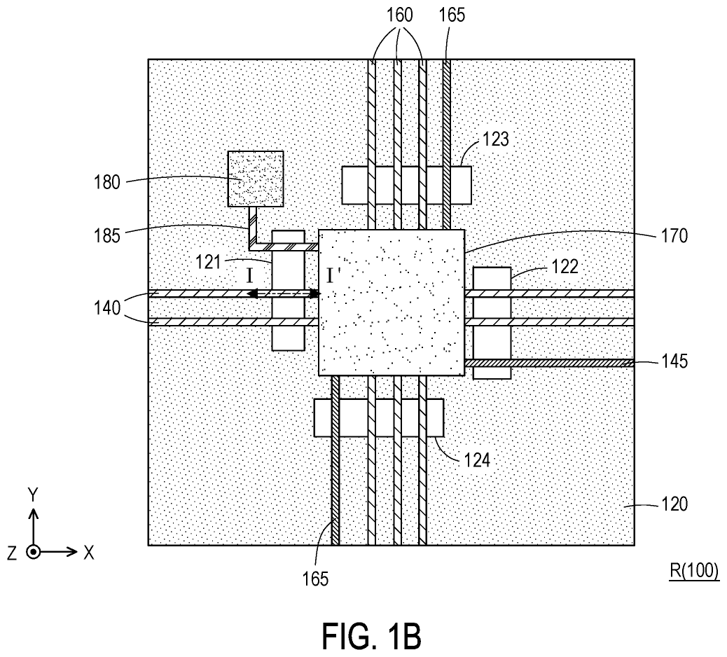

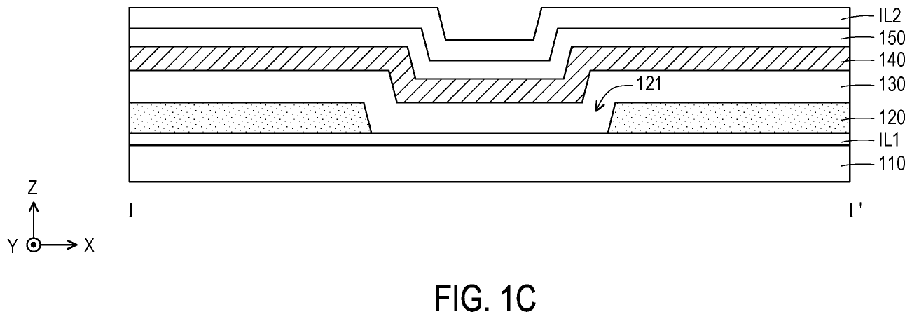

FIG. 1A is a top schematic view of the electronic device in the first embodiment of the disclosure. FIG. 1B is an enlarged schematic view of the area R of the electronic device in FIG. 1A. FIG. 1C is a cross-sectional schematic view of the electronic device in FIG. 1B along a profile line I-I′. For clarity and convenience of illustration, several elements in an electronic device are omitted in FIG. 1A and FIG. 1B.

Referring to FIG. 1A to FIG. 1C at the same time, the electronic device 100 of this embodiment may include a substrate 110, an insulating layer IL1, a metal layer 120, a first dielectric layer 130, a first conductive circuit 140, a first conductive circuit 145, a second dielectric layer 150, a second conductive circuit 160, a second conductive circuit 165, an insulating layer IL2, a driving chip 170, an electronic component 180, a third conductive circuit 185, a gate driver D1, and a source driver D2. The substrate 110 has an active area AA and a peripheral area PA adjacent to the active area AA. In this embodiment, the peripheral area PA may for example, surround the active area AA, but is not limited thereto. In some embodiment, the substrate 110 may include a rigid substrate, a flexible substrate or a combination of both. For example, the material of the substrate 110 may include glass, quartz, sapphire, ceramic, polycarbonate (PC), polyimide (PI), polyethylene terephthalate (PET), other suitable substrate materials, or a combination of the foregoing, but not limited thereto.

The insulating layer IL1 is provided on the substrate 110. In some embodiments, the insulating layer IL1 may be a single-layer structure or a multi-layer structure, and the material of the insulating layer IL1 may include organic material, inorganic material or a combination of the foregoing, but is not limited thereto.

The metal layer 120 is provided on the substrate 110 and the insulating layer IL1. The metal layer 120 is provided in the active area AA of the substrate 110. The metal layer 120 has a first opening 121, a first opening 122, a second opening 123, and a second opening 124 that are separated from each other. The first opening 121, the first opening 122, the second opening 123, and the second opening 124 may be adjacent to the driving chip 170 and may expose a part of the insulating layer IL1. In the top view of the electronic device 100 of this embodiment, as shown in FIG. 1B, the first opening 121, the first opening 122, the second opening 123, and the second opening 124 may be respectively provided around the driving chip 170, the first opening 121 and the first opening 122 may be respectively located on opposite sides of the driving chip 170, the second opening 123 and the second opening 124 may be respectively located on opposite sides of the driving chip 170, and the first opening 121, the first opening 122, the second opening 123, and the second opening 124 may not overlap the driving chip 170, but are not limited thereto.

The first dielectric layer 130 is provided on the metal layer 120. The first dielectric layer 130 may also be provided in the first opening 121, the first opening 122, the second opening 123, and the second opening 124 of the metal layer 120. In some embodiments, the first dielectric layer 130 may be a single-layer structure or a multi-layer structure, and the material of the first dielectric layer 130 may include organic material, inorganic material or a combination of the foregoing, but is not limited thereto.

The first conductive circuit 140 is provided on the metal layer 120 and the first dielectric layer 130. The first conductive circuit 140 may include a scan line, and the first conductive circuit 140 may be electrically connected to the gate driver D1 and the driving chip 170. The first conductive circuit 140 may extend substantially along direction X, but is not limited thereto. In the top view of the electronic device 100, as shown in FIG. 1B, the first conductive circuit 140 may overlap the first opening 121 and the first opening 122. In the cross-sectional view of the electronic device 100, as shown in FIG. 1C, the first conductive circuit 140 may overlap the first opening 121 in the normal direction (direction Z) of the substrate 110.

The first conductive circuit 145 is provided on the metal layer 120 and the first dielectric layer 130. The first conductive circuit 145 may include a first power line, and the first conductive circuit 145 may electrically connect the driving chip 170 and a power supply element (not shown). The first conductive circuit 145 may extend substantially along direction X, but is not limited thereto. In the top view of the electronic device 100, as shown in FIG. 1B, the first conductive circuit 145 may overlap the first opening 122. In addition, in this embodiment, the first conductive circuit 145 (i.e., the first power line) and the first conductive circuit 140 (i.e., the scan line) may be on the same layer, but are not limited thereto. In some embodiments, the first power line and the scan line may be on different layers, and the first power line may also be located above or below the scan line.

The second dielectric layer 150 is provided on the first conductive circuit 140 and the first conductive circuit 145. In some embodiments, the second dielectric layer 150 may be a single-layer structure or a multi-layer structure, and the material of the second dielectric layer 150 may include organic material, inorganic material or a combination of the foregoing, but is not limited thereto.

The second conductive circuit 160 is provided on the metal layer 120 and the second dielectric layer 150. The second conductive circuit 160 may include a data line, and the second conductive circuit 160 may be electrically connected to the source driver D2 and the driving chip 170. The second conductive circuit 160 may extend substantially along direction Y, but is not limited thereto. In the top view of the electronic device 100, as shown in FIG. 1B, the second conductive circuit 160 may overlap the second opening 123 and the second opening 124.

The second conductive circuit 165 is provided on the metal layer 120 and the second dielectric layer 150. The second conductive circuit 165 may include a second power line, and the second conductive circuit 165 may electrically connect the driving chip 170 and other power supply element (not shown). The second conductive circuit 165 may extend substantially along direction Y, but is not limited thereto. In the top view of the electronic device 100, as shown in FIG. 1B, the second conductive circuit 165 may overlap the second opening 123 and the second opening 124. In addition, in this embodiment, the second conductive circuit 165 (i.e., the second power line) and the second conductive circuit 160 (i.e., the scan line) may be on the same layer, but are not limited thereto. In some embodiments, the second power line and the scan line may be on different layers, and the second power line may also be located above or below the scan line.

In this embodiment, direction X, direction Y, and direction Z are different directions. Direction X is, for example, an extension direction of the first conductive circuit 140 or the scan line; direction Y is, for example, an extension direction of the second conductive circuit 160 or the data line, and direction Z is, for example, a normal direction of the substrate 110. Direction X is substantially perpendicular to direction Y, and direction X and direction Y are respectively substantially perpendicular to direction Z, but are not limited thereto.

The insulating layer IL2 is provided on the second dielectric layer 150. In some embodiments, the insulating layer IL2 may be a single-layer structure or a multi-layer structure, and the material of the insulating layer IL2 may include organic material, inorganic material or a combination of the foregoing, but is not limited thereto.

The driving chip 170 is provided on the metal layer 120 and the first dielectric layer 130. The driving chip 170 may be electrically connected to the first conductive circuit 140, the first conductive circuit 145, the second conductive circuit 160, the second conductive circuit 165, and the third conductive circuit 185, respectively. The driving chip 170 may be used to drive the electronic component 180. In this embodiment, the driving chip 170 may be provided in the active area AA of the substrate 110 by bonding or array arrangement, but is not limited thereto. The driving chip 170 may include a silicon-based IC or a glass-based IC, for example, a thin film transistor driving circuit formed on a glass substrate, but is not limited thereto.

The electronic component 180 is provided on the metal layer 120 and the first dielectric layer 130. The electronic component 180 is provided adjacent to the driving chip 170. The electronic component 180 may be electrically connected to the driving chip 170 through the third conductive circuit 185. In this embodiment, the electronic component 180 may include passive elements and/or active elements, such as capacitors, resistors, inductors, diodes, transistors, etc., but is not limited thereto. The diodes may include light-emitting diodes, photodiodes, or varactor diodes.

The third conductive circuit 185 is provided on the metal layer 120 and the first dielectric layer 130. The third conductive circuit 185 may be electrically connected to the electronic component 180 and the driving chip 170. In the top view of the electronic device 100, as shown in FIG. 1B, the third conductive circuit 185 may overlap the first opening 121. In addition, in this embodiment, the third conductive circuit 185 and the first conductive circuit 140 (i.e., the scan line) may be on the same layer, but are not limited thereto. In some embodiments, in addition to the first dielectric layer, there are also other dielectric layers. The third conductive circuit and the scan line may be on different layers, and the third conductive circuit may also be located above or below the scan line and have a dielectric layer between the scan line. In some embodiments, in addition to the first dielectric layer, there also are other dielectric layers. The third conductive circuit, the scan line, the data line, and the power line may be on different layers, and dielectric layers may be provided therebetween.

In this embodiment, by providing the openings (including the first opening 121, the first opening 122, the second opening 123, and the second opening 124) through the metal layer 120 near the driving chip 170 and causing at least one part of the conductive circuits (including the first conductive circuit 140, the first conductive circuit 145, the second conductive circuit 160, the second conductive circuit 165, and the third conductive circuit 185) electrically connected to the driving chip 170 to overlap the openings, the at least one part may be kept off of the metal layer 120. Thus, when patching the at least one part or performing a function analysis or a failure analysis to the electronic device 100 using the at least one part, the risk of a short circuit between the conductive circuits and the metal layer 120 below may be reduced. For example, to patch a problematic part in a conductive circuit, the conductive circuit of the part is usually first removed by laser cutting before performing patching. However, laser cutting not only cuts off the conductive circuit of the part, it also cuts off the dielectric layer below. Thus, when there is no opening near the driving chip or the conductive circuit of the part does not overlap the opening, after laser cutting, the metal layer may be exposed, so that the conductive circuit after patching comes into contact with the exposed metal layer and causes a short circuit.

Although the first conductive circuits (i.e., the first conductive circuit 140 and the first conductive circuit 145) and the second conductive circuits (i.e., the second conductive circuit 160 and the second conductive circuit 165) in this embodiment may be on different layers, and the first conductive circuits (i.e., the first conductive circuit 140 and the first conductive circuit 145) and the third conductive circuit 185 may be on the same layer, the disclosure is not limited thereto. In some embodiments not shown, the first conductive circuit, the second conductive circuit, and the third conductive circuit may also be provided on the same layer.

Other embodiments are described below for illustrative purposes. It is to be noted that the following embodiments use the reference numerals and a part of the contents of the above embodiments, and the same reference numerals are used to denote the same or similar elements, and the description of the same technical contents is omitted. For the description of the omitted part, reference may be made to the above embodiments, and details are not described in the following embodiments.

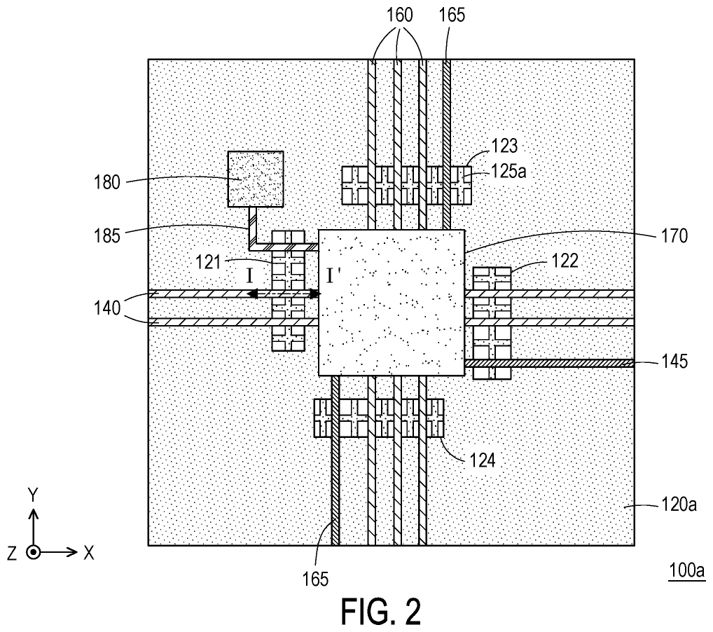

FIG. 2 is a partial top schematic view of the electronic device in the second embodiment of the disclosure. Referring to FIG. 2 and FIG. 1B at the same time, the electronic device 100a of this embodiment is similar to the electronic device 100 in FIG. 1B. The difference between the two is: the electronic device 100a of this embodiment further includes a metal mesh 125a.

Specifically, referring to FIG. 2, the metal mesh 125a is provided in the first opening 121, the first opening 122, the second opening 123, and the second opening 124. The metal mesh 125a may include grid-like staggered metal lines. In this embodiment, the metal mesh 125a may be a part of the metal layer 120a, but is not limited thereto. In some embodiments, when the metal mesh 125a is a part of the metal layer 120a and the metal mesh 125a and the conductive circuits (i.e., the first conductive circuit 140, the first conductive circuit 145, the second conductive circuit 160, or the second conductive circuit 165) are on different layers, the metal mesh 125a may overlap the conductive circuits (i.e., the first conductive circuit 140, the first conductive circuit 145, the second conductive circuit 160, or the second conductive circuit 165), but is not limited thereto.

When the electronic device is a display device, the metal mesh 125a may be used to adjust the opening rate of the openings (including the first opening 121, the first opening 122, the second opening 123, and the second opening 124) to reduce the risk of light leakage. When the electronic device is an antenna device, the size and amount of the holes of the metal mesh 125a may also be used to adjust the frequency (or wavelength) that the electronic device 100a may emit or receive.

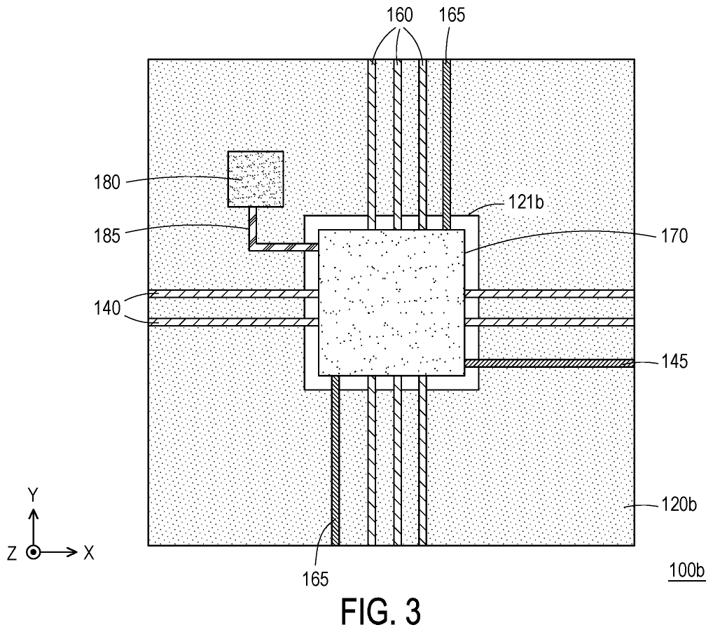

FIG. 3 is a partial top schematic view of the electronic device in the third embodiment of the disclosure. Referring to FIG. 3 and FIG. 1B at the same time, the electronic device 100b of this embodiment is similar to the electronic device 100 in FIG. 1B. The difference between the two is: in the electronic device 100b of this embodiment, the first opening 121, the first opening 122, the second opening 123, and the second opening 124 in the electronic device 100 are replaced by a first opening 121b with a larger size.

Specifically, referring to FIG. 3, the metal layer 120b has a first opening 121b, and the first opening 121b is provided below the driving chip 170. The driving chip 170 may overlap the first opening 121b, and the first conductive circuit 140, the first conductive circuit 145, the second conductive circuit 160, the second conductive circuit 165, and the third conductive circuit 185 may overlap the first opening 121b. In addition, in this embodiment, the size of the first opening 121b may be, for example, larger than the size of the driving chip 170, but is not limited thereto.

In this embodiment, by providing the first opening 121b below the driving chip 170 and causing at least one part of the conductive circuits (including the first conductive circuit 140, the first conductive circuit 145, the second conductive circuit 160, the second conductive circuit 165, and the third conductive circuit 185) electrically connected to the driving chip 170 to overlap the first opening 121b, the at least one part may be kept off of the metal layer 120b. Thus, when patching the at least one part or performing a function analysis or a failure analysis to the electronic device 100b using the at least one part, the risk of a short circuit between the conductive circuits and the metal layer 120b below may be reduced.

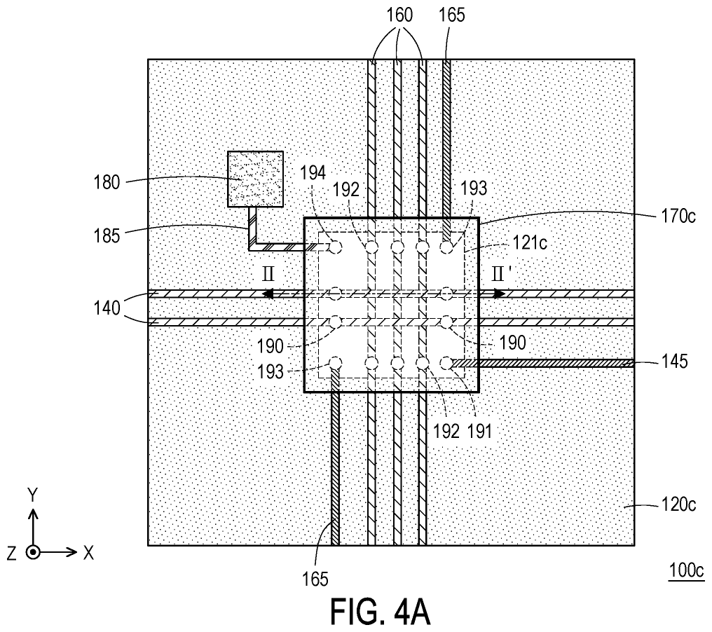

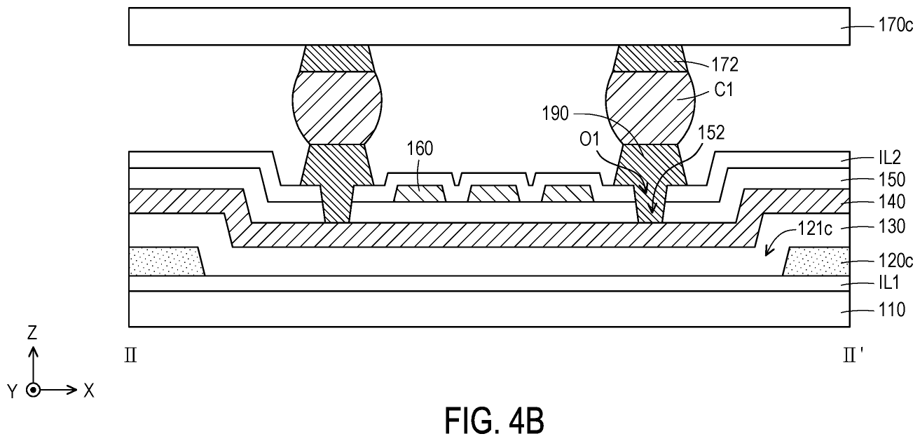

FIG. 4A is a partial top schematic view of the electronic device in the fourth embodiment of the disclosure. FIG. 4B is a cross-sectional schematic view of the electronic device in FIG. 4A along a profile line II-II′. Referring to FIG. 4A to FIG. 4B and FIG. 1B at the same time, the electronic device 100c of this embodiment is similar to the electronic device 100 in FIG. 1B. The differences between the two are: in the electronic device 100c of this embodiment, the first opening 121, the first opening 122, the second opening 123, and the second opening 124 in the electronic device 100 are replaced by a first opening 121c with a larger size, and the driving chip 170c is bonded to the active area AA of the substrate 110 in a flip chip manner.

Specifically, referring to FIG. 4A and FIG. 4B, the metal layer 120c has a first opening 121c provided below the driving chip 170c. The driving chip 170c may overlap the first opening 121c, and the first conductive circuit 140, the first conductive circuit 145, the second conductive circuit 160, the second conductive circuit 165, and the third conductive circuit 185 may overlap the first opening 121c. The first conductive circuit 140, the first conductive circuit 145, the second conductive circuit 160, the second conductive circuit 165, and the third conductive circuit 185 may overlap the driving chip 170c. In addition, in this embodiment, the size of the first opening 121c may be, for example, smaller than the size of the driving chip 170c, but is not limited thereto.

In this embodiment, the second dielectric layer 150 has a third opening 152. The third opening 152 may expose a part of the first conductive circuit 140. The third opening 152 may overlap the first opening 121c in the normal direction (direction Z) of the substrate 110.

In this embodiment, the insulating layer IL2 has the opening O1. The opening O1 may connect the third opening 152, and the opening O1 may overlap the first opening 121c in the normal direction (direction Z) of the substrate 110.

In this embodiment, the electronic device 100c further includes a first conductive pad 190 that penetrates the second dielectric layer 150 and the insulating layer IL2. The first conductive pad 190 is provided on the second dielectric layer 150 and the insulating layer IL2, and the first conductive pad 190 may also be provided in the third opening 152 and the opening O1.

The first conductive pad 190 may be in contact with the first conductive circuit 140. The first conductive pad 190 may overlap the first opening 121c and the driving chip 170c in the normal direction (direction Z) of the substrate 110.

In this embodiment, the electronic device 100c further includes a conductive member C1, and the conductive member C1 is provided on the first conductive pad 190.

In this embodiment, the driving chip 170c may be provided on the first opening 121c. The driving chip 170c may include a pad 172. The pad 172 may be provided on the surface of the driving chip 170c facing the substrate 110. In this embodiment, the pad 172 of the driving chip 170c may be connected to the first conductive pad 190 through the conductive member C1, so that the driving chip 170c may be electrically connected to the first conductive circuit 140 through the pad 172, the conductive member C1, and the first conductive pad 190.

In this embodiment, the electronic device 100c further includes a first conductive pad 191, a first conductive pad 192, a first conductive pad 193, and a first conductive pad 194 provided on the substrate 110. The first conductive pad 191, the first conductive pad 192, the first conductive pad 193, and the first conductive pad 194 may overlap the first opening 121c and the driving chip 170c in the normal direction (direction Z) of the substrate 110. The driving chip 170c may be electrically connected to the first conductive circuit 145 through the first conductive pad 191, the driving chip 170c may be electrically connected to the second conductive circuit 160 through the first conductive pad 192, the driving chip 170c may be electrically connected to the second conductive circuit 165 through the first conductive pad 193, and the driving chip 170c may be electrically connected to the third conductive circuit 185 through the first conductive pad 194.

In this embodiment, by providing the first opening 121c below the driving chip 170c and causing at least one part of the conductive circuits (including the first conductive circuit 140, the first conductive circuit 145, the second conductive circuit 160, the second conductive circuit 165, and the third conductive circuit 185) electrically connected to the driving chip 170c to overlap the first opening 121c, the at least one part may be kept off of the metal layer 120c. Thus, when patching the at least one part or performing a function analysis or a failure analysis to the electronic device 100c using the at least one part, the risk of a short circuit between the conductive circuits and the metal layer 120c below may be reduced.

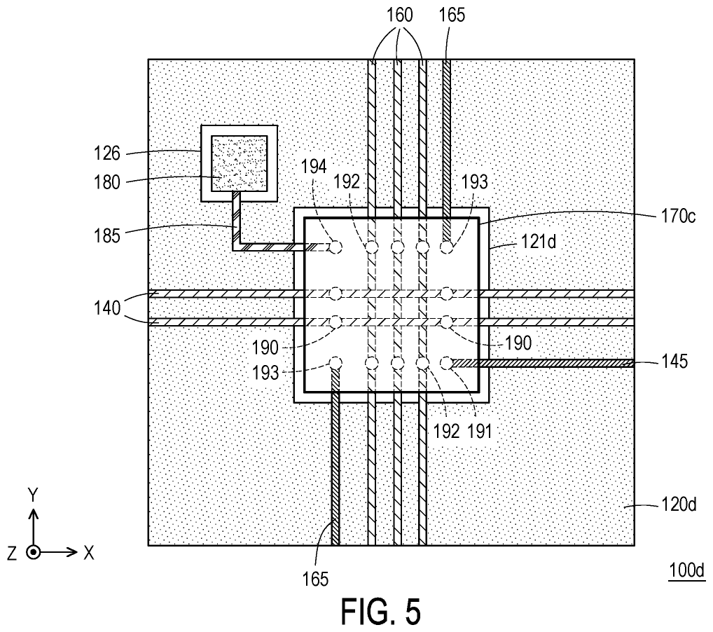

FIG. 5 is a partial top schematic view of the electronic device in the fifth embodiment of the disclosure. Referring to FIG. 5 and FIG. 4A at the same time, the electronic device 100d of this embodiment is similar to the electronic device 100c in FIG. 4A. The difference between the two is: in the electronic device 100d of this embodiment, the first opening 121c in the electronic device 100c is replaced by a first opening 121d with a size larger than the driving chip 170c. In addition, the metal layer 120d further has a fourth opening 126.

Specifically, referring to FIG. 5, the fourth opening 126 is provided below the electronic component 180, and the electronic component 180 may overlap the fourth opening 126. The fourth opening 126 and the first opening 121d are separated from each other. In this embodiment, the size of the fourth opening 126 may be, for example, larger than the size of the electronic component 180, but is not limited thereto. In addition, the third conductive circuit 185 may overlap the fourth opening 126.

In this embodiment, by providing the fourth opening 126 below the electronic component 180 and causing at least one part of the third conductive circuit 185 electrically connected to electronic component 180 to overlap the fourth opening 126, the at least one part may be kept off of the metal layer 120d. Thus, when patching the at least one part or performing a function analysis or a failure analysis to the electronic device 100d using the at least one part, the risk of a short circuit between the third conductive circuit 185 and the metal layer 120d below may be reduced.

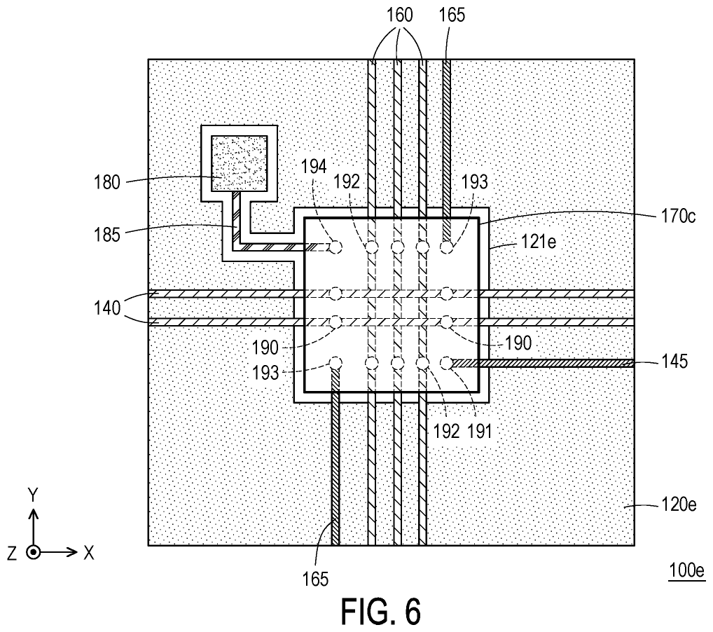

FIG. 6 is a partial top schematic view of the electronic device in the sixth embodiment of the disclosure. Referring to FIG. 6 and FIG. 5 at the same time, the electronic device 100e of this embodiment is similar to the electronic device 100d in FIG. 5. The difference between the two is: in the electronic device 100e of this embodiment, the first opening 121d and the fourth opening 126 in the electronic device 100d are replaced by a first opening 121e with a larger size.

Specifically, referring to FIG. 6, the metal layer 120e has the first opening 121e, and the first opening 121e is provided below the driving chip 170c, the third conductive circuit 185, and the electronic component 180. The driving chip 170c, the third conductive circuit 185, and the electronic component 180 may all overlap the first opening 121e, and the first conductive circuit 140, the first conductive circuit 145, the second conductive circuit 160, and the second conductive circuit 165 may overlap the first opening 121e. In this embodiment, the size of the first opening 121e may be, for example, larger than the sum of the sizes of the driving chip 170c, the third conductive circuit 185, and the electronic component 180, but is not limited thereto.

In this embodiment, by providing the first opening 121e below the third conductive circuit 185, the third conductive circuit 185 is not on the metal layer 120e. Thus, when patching the third conductive circuit 185 or performing a function analysis or a failure analysis to the electronic device 100e using the third conductive circuit 185, the risk of a short circuit between the third conductive circuit 185 and the metal layer 120e below may be reduced.

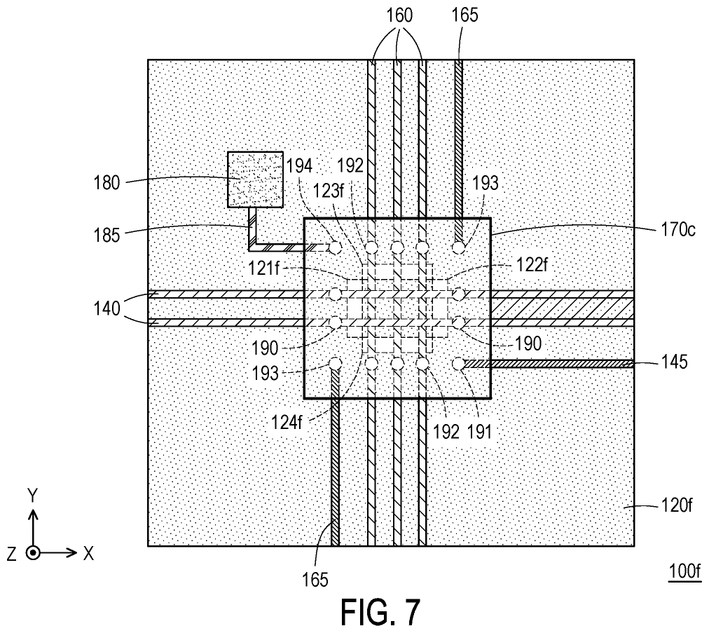

FIG. 7 is a partial top schematic view of the electronic device in the seventh embodiment of the disclosure. Referring to FIG. 7 and FIG. 4A at the same time, the electronic device 100f of this embodiment is similar to the electronic device 100c in FIG. 4A. The difference between the two is: in the electronic device 100f of this embodiment, the first opening 121c in the electronic device 100c is replaced by a first opening 121f, a first opening 122f, a second opening 123f, and a second opening 124f with smaller sizes.

Specifically, referring to FIG. 7, the metal layer 120f has the first opening 121f, the first opening 122f, the second opening 123f, and the second opening 124f that are separated from each other. The first opening 121f, the first opening 122f, the second opening 123f, and the second opening 124f are provided below the driving chip 170c, and the driving chip 170c may overlap the first opening 121f, the first opening 122f, the second opening 123f, and the second opening 124f. In this embodiment, the size of the driving chip 170c may be, for example, larger than the size of the first opening 121f, the first opening 122f, the second opening 123f and, the second opening 124f, but is not limited thereto.

In this embodiment, the first conductive circuit 140 may overlap the first opening 121f and the first opening 122f. The second conductive circuit 160 may overlap the second opening 123f and the second opening 124f. In addition, the first conductive circuit 145 does not overlap the first opening 122f, the second conductive circuit 165 does not overlap the second opening 123f and the second opening 124f, and the third conductive circuit 185 does not overlap the first opening 121f.

In this embodiment, the first conductive pad 190, the first conductive pad 191, the first conductive pad 192, the first conductive pad 193, and the first conductive pad 194 may overlap the driving chip 170c in the normal direction (direction Z) of the substrate 110 and may not overlap the first opening 121f, the first opening 122f, the second opening 123f, and the second opening 124f.

In this embodiment, by providing the openings (including the first opening 121f, the first opening 122f, the second opening 123f, and the second opening 124f) below the driving chip 170c and causing at least one part of the conductive circuits (including the first conductive circuit 140 and the second conductive circuit 160) electrically connected to the driving chip 170c to overlap the openings, the at least one part may be kept off of the metal layer 120f. Thus, when patching the at least one part or performing a function analysis or a failure analysis to the electronic device 100f using the at least one part, the risk of a short circuit between the conductive circuits and the metal layer 120f below may be reduced.

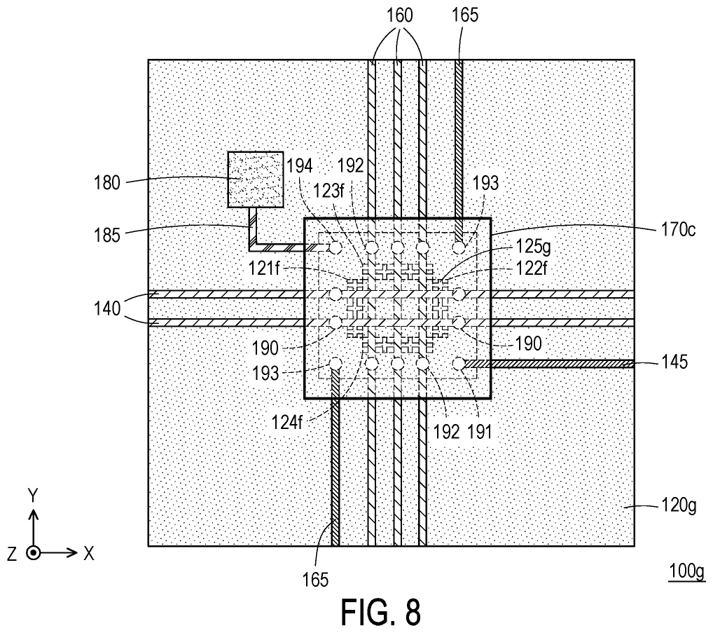

FIG. 8 is a partial top schematic view of the electronic device in the eighth embodiment of the disclosure. Referring to FIG. 8 and FIG. 7 at the same time, the electronic device 100g of this embodiment is similar to the electronic device 100f in FIG. 7. The difference between the two is: the electronic device 100g of this embodiment further includes a metal mesh 125g.

Specifically, referring to FIG. 8, the metal mesh 125g is provided in the first opening 121f, the first opening 122f, the second opening 123f, and the second opening 124f. The metal mesh 125g may include grid-like staggered metal lines. In this embodiment, the metal mesh 125g may be a part of the metal layer 120g, but is not limited thereto. In some embodiments, the metal mesh may also be another metal layer.

When the electronic device is a display device, the metal mesh 125g may be used to adjust the opening rate of the openings (including the first opening 121f, the first opening 122f, the second opening 123f, and the second opening 124f) to reduce the risk of light leakage. When the electronic device is an antenna device, the size and amount of the holes of the metal mesh 125g may also be used to adjust the frequency (or wavelength) that the electronic device 100g may emit or receive.

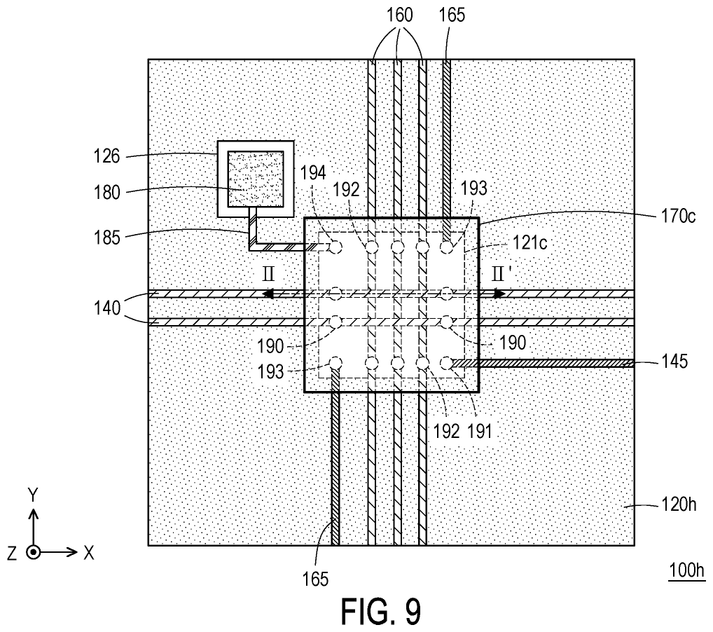

FIG. 9 is a partial top schematic view of the electronic device in the ninth embodiment of the disclosure. Referring to FIG. 9 and FIG. 4A at the same time, the electronic device 100h of this embodiment is similar to the electronic device 100c in FIG. 4A. The difference between the two is: in the electronic device 100h of this embodiment, the metal layer 120h further has a fourth opening 126.

Specifically, referring to FIG. 9, the fourth opening 126 is provided below the electronic component 180, and the electronic component 180 may overlap the fourth opening 126. The fourth opening 126 and the first opening 121c are separated from each other. In this embodiment, the size of the fourth opening 126 may be, for example, larger than the size of the electronic component 180, but is not limited thereto. In addition, the third conductive circuit 185 may overlap the fourth opening 126.

In this embodiment, by providing the fourth opening 126 below the electronic component 180 and causing at least one part of the third conductive circuit 185 electrically connected to electronic component 180 to overlap the fourth opening 126, the at least one part may be kept off of the metal layer 120h. Thus, when patching the at least one part or performing a function analysis or a failure analysis to the electronic device 100h using the at least one part, the risk of a short circuit between the third conductive circuit 185 and the metal layer 120h below may be reduced.

To sum up, in the electronic device of the disclosure, by providing an opening near or below the driving chip and causing at least one part of the conductive circuit electrically connected to the driving chip to overlap the opening, the at least one part may kept off of the metal layer.

Thus, when patching the at least one part or performing a function analysis or a failure analysis to the electronic device using the at least one part, the risk of a short circuit between the conductive circuits and the metal layer below may be reduced. In addition, when a metal mesh is provided in the opening, the opening rate of the opening may be adjusted to reduce the risk of light leakage, or the frequency (or wavelength) at which the electronic device is emitted or received may be adjusted.

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments can still be modified, or parts or all of the technical features thereof can be equivalently replaced;

however, these modifications or substitutions do not deviate the essence of the corresponding technical solutions from the scope of the technical solutions of the embodiments of the disclosure.

What is claimed is:

1. An electronic device, comprising:
a substrate;
a metal layer, provided on the substrate and having a first opening;
a first dielectric layer, provided on the metal layer;
a first conductive circuit, provided on the first dielectric layer; and
a driving chip, provided on the first dielectric layer and electrically connected to the first conductive circuit,
wherein the first opening is adjacent to the driving chip, and the first conductive circuit overlaps the first opening.

2. The electronic device according to claim 1, wherein the first conductive circuit comprises a scan line or a first power line.

3. The electronic device according to claim 1, wherein the first dielectric layer is provided in the first opening.

4. The electronic device according to claim 1, wherein the metal layer further has a second opening, and the electronic device further comprises:
a second dielectric layer, provided on the first conductive circuit; and
a second conductive circuit, provided on the second dielectric layer and electrically connected to the driving chip,
wherein the second opening is adjacent to the driving chip, and the second conductive circuit overlaps the second opening.

5. The electronic device according to claim 4, wherein the second conductive circuit comprises a data line or a second power line.

6. The electronic device according to claim 4, further comprising:
a metal mesh, provided in the second opening.

7. The electronic device according to claim 4, wherein the first opening and the second opening do not overlap the driving chip.

8. The electronic device according to claim 4, wherein the driving chip overlaps the first opening and the second opening.

9. The electronic device according to claim 1, further comprising:
a metal mesh, provided in the first opening.

10. The electronic device according to claim 1, wherein the metal mesh is a part of the metal layer.

11. The electronic device according to claim 1, further comprising:
a second dielectric layer, provided on the first conductive circuit; and
a second conductive circuit, provided on the second dielectric layer and electrically connected to the driving chip,
wherein the driving chip overlaps the first opening, and the second conductive circuit overlaps the first opening.

12. The electronic device according to claim 1, further comprising:
a second dielectric layer, provided on the first conductive circuit and having a third opening;
a first conductive pad, provided on the second dielectric layer and in the third opening,
wherein the driving chip is electrically connected to the first conductive circuit through the first conductive pad.

13. The electronic device according to claim 12, wherein the first conductive pad overlaps the first opening and the driving chip.

14. The electronic device according to claim 1, wherein the metal layer further has a fourth opening, and the electronic device further comprises:
an electronic component; and
a third conductive circuit, electrically connecting the electronic component and the driving chip;
wherein the electronic component overlaps the fourth opening.

15. The electronic device according to claim 14, wherein the third conductive circuit overlaps the first opening.

16. The electronic device according to claim 14, wherein the third conductive circuit is provided on the second dielectric layer.

17. The electronic device according to claim 14, wherein the fourth opening is larger than the electronic component.

18. The electronic device according to claim 1, wherein the driving chip overlaps the first opening, and the driving chip is larger than the first opening.

19. The electronic device according to claim 1, wherein the driving chip overlaps the first opening, and the first opening is larger than the driving chip.

20. The electronic device according to claim 1, further comprising:
an electronic component; and
a third conductive circuit, electrically connecting the electronic component and the driving chip;
wherein the driving chip, the third conductive circuit, and the electronic component overlap the first opening.
